(19) United States
(12) Patent Application Publication
(10) Pub. No.: US 2024/0328512 A1
(43) Pub. Date: Oct. 3, 2024

(54) METHODS AND APPARATUS TO REDUCE LEAKAGE OF COOLING FLUID USED TO COOL AN ELECTRONIC COMPONENT

(71) Applicant: Intel Corporation, Santa Clara, CA (US)

(72) Inventors: Craig Yost, Gilbert, AZ (US); Paul Jonathan Diglio, Gaston, OR (US); Ruben Eduardo Nunez Blanco, Gilbert, AZ (US)

(21) Appl. No.: 18/192,429

(22) Filed: Mar. 29, 2023

(51) Int. Cl. F16J 15/06; H05K 7/20

(52) U.S. Cl. CPC F16J 15/06; H05K 7/20009

(57) ABSTRACT

Methods, apparatus, systems, and articles of manufacture are disclosed that reduce leakage of a cooling fluid used to cool an electronic component. An example disclosed herein includes a seal assembly comprising a socket to receive an electronic component, the electronic component including a semiconductor die and a substrate to support the die, a first seal to be forced against the electronic component, the first seal to surround the die, and a second seal to be forced against the electronic component, the second seal to surround the first seal.

### FIELD OF THE DISCLOSURE

This disclosure relates generally to electronic component cooling and, more particularly, to methods and apparatus to reduce leakage of cooling fluid used to cool an electronic component.

### BACKGROUND

Electronic components (e.g., processors) generate heat during operation, requiring cooling to prevent the electronic device from overheating resulting in performance loss and/or damage. Some electronic components are cooled using heat dissipation/transfer through a fluid interfacing with the electronic component. Sometimes, the fluid directly contacts the electronic component to increase heat dissipation/transfer by eliminating an extra interfacing component.

### BRIEF DESCRIPTION OF THE DRAWINGS

FIG. 1 shows a first example seal assembly.

FIG. 2 shows a detailed cross-sectional view of a second example seal assembly.

FIG. 3 shows a top view of the second example seal assembly of FIG. 2.

FIG. 4 shows an isometric view of an example first seal in the example seal assembly of FIGS. 2 and 3.

FIG. 5 shows a detailed cross-sectional view of a third example seal assembly.

FIG. 6 shows a bottom view of the third example seal assembly of FIG. 5.

FIG. 7 shows isometric views of an example second seal in the third example seal assembly of FIGS. 5 and 6.

FIG. 8 shows an exploded view of the third example seal assembly of FIGS. 5-7.

FIG. 9 is a flowchart representative of an example process for implementing the example seal assemblies of any one of FIGS. 1-8.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmable with instructions to perform specific operations and including one or more semiconductor-based logic devices (e.g., electrical hardware implemented by one or more transistors). Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of processor circuitry is/are best suited to execute the computing task(s).

### DETAILED DESCRIPTION

Electronic components continue to get smaller over time, and with that, thermal densities (e.g., heat generated per measure of volume) of the electronic components increase to be able to maintain the same or better performance. To cool these electronic components, direct fluid cooling (e.g., cooling the electronic component by interfacing fluid/liquid directly with the electronic component) is one option to reduce (e.g., prevent) overheating, throttling, and/or damage.

A challenge with direct fluid cooling is the possibility of the cooling fluid (e.g., coolant) leaking and coming into contact with electrical connections on the electronic component and/or into contact with a socket/receptacle electrically coupled to and/or holding the electronic component inserted therein. Fluid leaks into the socket/receptacle or wherever the electronic component is interfacing with electricity can cause costly damage and/or failures. Accordingly, seals may be employed to contain the coolant and reduce (e.g., prevent) leaks. However, implementing effective and/or reliable seals can be challenging due to uneven electronic component surfaces, foreign material that is present on the electronic component, seal wear-out resulting in damage or failure to the seal, etc.

Existing sealing solutions utilize a single seal to prevent fluid from the direct fluid cooling system from leaking out of the seal. Single seal solutions cause problems where the seal fails since there is no redundancy or additional safety measure in place to prevent catastrophic failures. Therefore, there exists a need to implement a sealing assembly to prevent fluid leaks while maintaining device operability and performance.

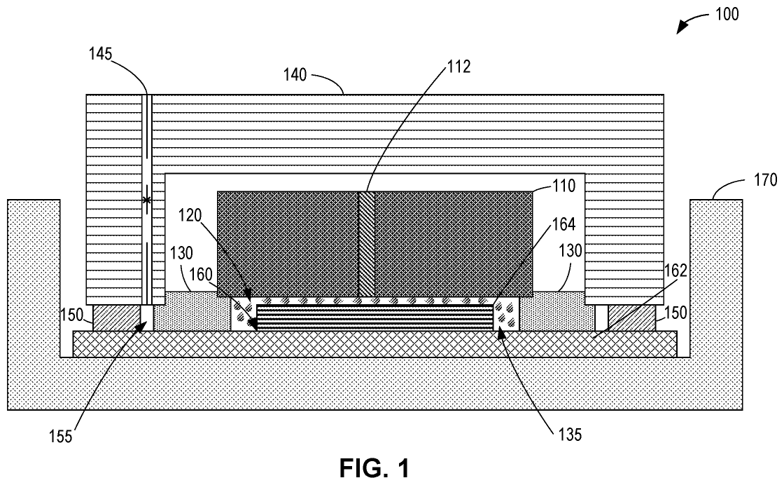

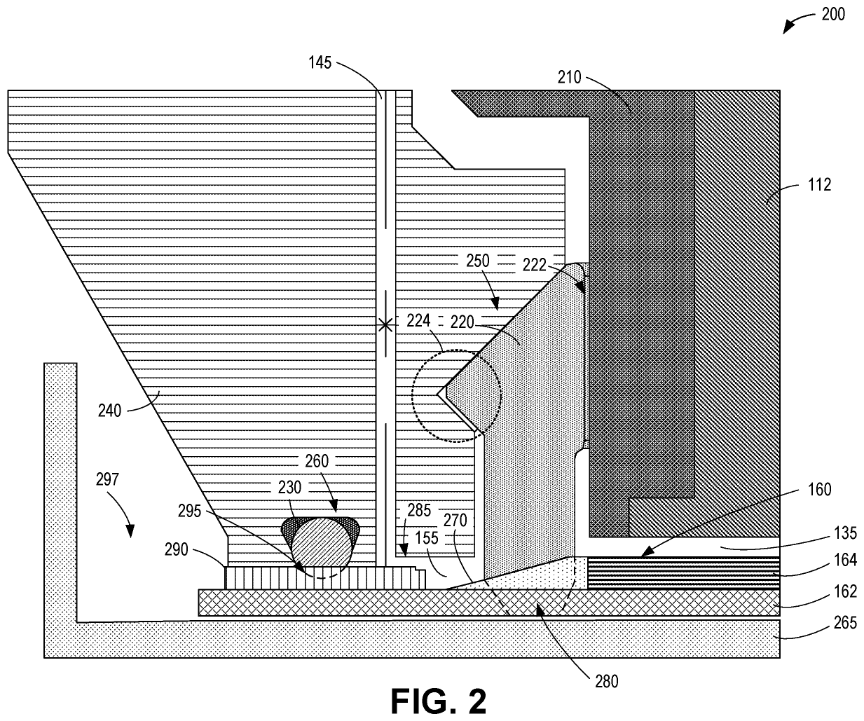

FIG. 1 is a cross-sectional schematic view of an example seal assembly 100. The components shown in the example seal assembly 100 of FIG. 1 are simplified for purposes of explanation to generically describe the components of examples disclosed herein. More detailed examples are shown and described in connection with FIGS. 2-8. The example seal assembly 100 includes a die force applicator 110, a cooling fluid 120, a first seal 130, a package force applicator 140, and a second seal 150. In the example illustration of FIG. 1, an example electronic component 160 interfaces with a socket 170. In some examples, the socket 170 may be on a motherboard of a computer (e.g., a printed circuit board (PCB)), a breadboard, a protoboard, etc. In some examples, the cooling fluid 120 may include water, deionized water, glycol/water solutions, and dielectric fluids such as fluorocarbons, or any other suitable cooling fluid.

The example electronic component 160 disclosed herein may include in any suitable electronic component such as a semiconductor die, an integrated circuit (IC), logic circuits, Field Programmable Gate Arrays (FPGAs), microprocessors, Central Processor Units (CPUs), Graphics Processor Units (GPUs), Digital Signal Processors (DSPs), and/or microcontrollers from any desired family or manufacturer. In some examples, the electronic component 160 may include a substrate 162 to interface with the socket 170 and a semiconductor die 164 to interface with the die force applicator 110 and/or the cooling fluid 120. In some examples, the cooling fluid 120 may also interface with the substrate 162 depending on cooling needs and/or design of the electronic component 160. In some examples, the die 164 is enclosed in a housing (e.g., mold) of an IC package that includes the substrate 162. In such examples, the die 164 does not directly interface with the die force applicator 110 or the cooling fluid 120. Instead, the die force applicator 110 or the cooling fluid 120 directly interface with the housing of the IC package containing the die 164. In some examples, the electronic component 160 includes more than one die 164. Likewise, in some examples, the package force applicator 140 does not directly interface with the substrate 162. Instead, the package force applicator 140 interfaces with a device stiffener (discussed further in FIG. 2).

In some examples, the die force applicator 110 and/or the package force applicator 140 provide a compressive force to the first seal 130 and the electronic component 160. The compressive force ensures that the electronic component 160 is interfacing correctly with the socket 170 (e.g., enforcing an electrical connection between the substrate 162 and the socket 170). In some examples, the die force applicator 110 includes at least one fluid channel 112 to introduce, remove, and/or circulate the cooling fluid 120 within an area immediately surrounding the die 164 (or an associated housing) within the first seal 130.

In some examples, the first seal 130 defines a first sealed area 135. That is, the first seal 130 circumscribes, encompasses, or encloses the first seal area 135. The first sealed area 135 is dimensioned to enable the die 164 to be positioned therein with additional space for the cooling fluid 120 to circulate around the die 164. In some examples, the circulation of the cooling fluid 120 is forced circulation (e.g., based on fluid being pumped into and/or out of the first sealed area 135). Additionally or alternatively, in some examples, the circulation of the cooling fluid 120 is based on natural circulation. In some examples, the first seal 130 is forced or urged against the electronic component 160 via the die force applicator 110 to ensure the first sealed area 135 is sealed to prevent the cooling fluid 120 from escaping the first sealed area 135. In some examples, the first seal 130 can be forced against the electronic component 160 by another device such as the package force applicator 140. Further, in some examples, the first seal may be forced against the electronic component 160 via both the die force applicator 110 and the package force applicator 140.

In examples disclosed herein, the first sealed area 135 is pressurized to a first pressure. In the examples disclosed herein, the first pressure can be less than, equal to, or greater than standard day ambient atmospheric pressure at sea level. The first pressure may increase or decrease based on the type of cooling fluid 120 being used, the particular application for the electronic component, the size of the first sealed area 135, etc., and may be dynamically monitored/modified based on sensed conditions inside the first sealed area 135, the workload on the electronic component 160, etc. In some examples, pressurizing the first sealed area 135 removes air/steam pockets that may occur in the cooling system and allows the cooling fluid 120 to interface with the entirety of the electronic component 160 equally, preventing hot spots from forming (e.g., localized areas of the electronic component 160 being hotter than other areas).

In some examples, the package force applicator 140 provides a compressive force to the second seal 150 and the electronic component 160. As disclosed above, the compressive force can ensure that the electronic component 160 is interfacing correctly with the socket 170 (e.g., enforcing an electrical connection between the substrate 162 and the socket 170).

In some examples, the second seal 150 defines a second sealed area 155 that surrounds the first sealed area 135. That is, the second sealed area 155 is the area between the first and second seals 130, 150. In some examples, the second seal 150 is forced or urged against the electronic component 160 via the package force applicator 140 to ensure the second sealed area 155 is sealed. More particularly, in some examples, as shown in FIG. 1, the second seal 150 is forced or urged against a portion of the substrate 162 that extends outward beyond the first seal 130. In some examples, the second seal 150 can be forced against the electronic component 160 via another device and/or a different system altogether. In the event that the first seal 130 fails, where the cooling fluid 120 can leak outside of the first sealed area 135, the second seal 150 serves to maintain the fluid 120 in the second sealed area 155 and prevent the cooling fluid 120 from leaking into the socket 170. Additionally or alternatively, in some examples, the second pressure in the second sealed area 155 is measured such that changes to the second pressure due to the first seal 130 failing can be detected indicating a failure.

In some examples, the second sealed area 155 is pressurized with a pressurized gas to a second pressure that is greater than the first pressure of the first sealed area 135. In some examples, the second pressure of the second sealed area 155 is at least 0.1 atmospheres (atm) above the first pressure of the first sealed area 135. In some examples, the pressurized gas is air, but any other suitable pressurized gas, such as nitrogen, helium, etc., may be used herein to pressurize the second sealed area 155. The second pressure may be increased or decreased based on the load applied to the socket 170, the value of the first pressure, the type of pressurized gas being used, etc. Thus, in some examples, if the first pressure of the first sealed area 135 is less than 2.5 atm, the second pressure of the second sealed area 155 may be less than 3 atm.

In the examples disclosed herein, the second pressure is greater than the first pressure to force the cooling fluid 120 back into the first sealed area 135 (and/or prevent the fluid 120 from leaking past the first seal 130 in the first place) in the event the first seal 130 fails. That is, rather than the cooling fluid 120 leaking past the first seal 130 that has failed, the pressurized gas (e.g., air) in the second sealed area 155 will be forced into the first sealed area 135 due to the pressure differential on either side of the first seal 130. The second sealed area 155 being supplied with pressurized gas (instead of another cooling fluid) further prevents the possibility of the cooling fluid 120 from leaking into the socket 170 by providing a gas barrier to protect the socket 170 in the event that the second seal 150 were to fail.

In some examples, the package force applicator 140 includes a pressurized gas channel 145 for delivering the pressurized gas to the second sealed area 155. In some examples, the package force applicator 140 may include more than one pressurized gas channel 145 spaced throughout the second sealed area 155. The pressurized gas channel 145 may be utilized as a circulation channel (e.g., moving pressurized gas to/from the second sealed area 155).

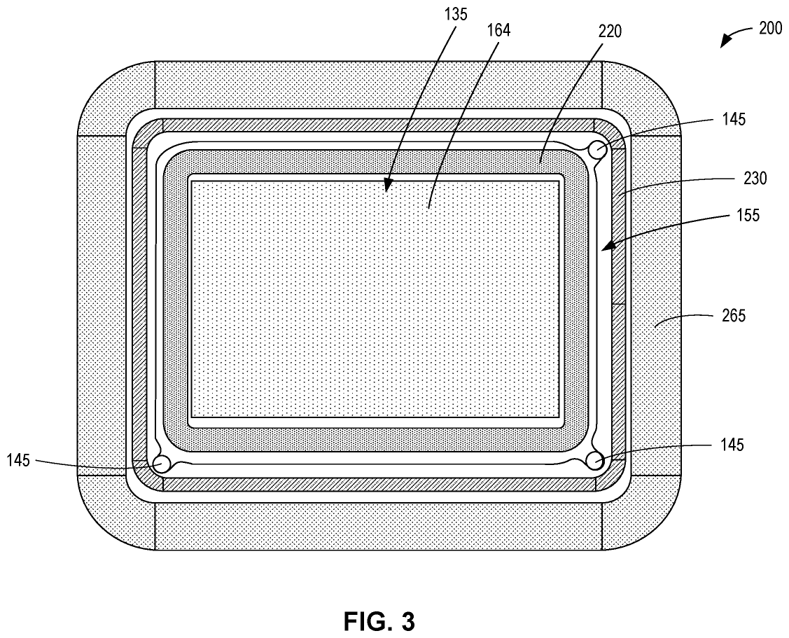

FIG. 2 shows a detailed cross-sectional view of a second example seal assembly 200. FIG. 3 is a top view of the second example seal assembly 200. The second example seal assembly 200 includes an example first die force applicator 210, an example first seal 220, an example second seal 230, and an example first package force applicator 240. In the illustrated example of FIG. 3, the die force applicator 210 and portions of the package force applicator 240 are omitted to provide a clear view of the spatial relationship of the seals 220, 230. The first die force applicator 210, the first seal 220, the second seal 230, and the first package force applicator 240 are respectively comparable in function, purpose, and operation to the die force applicator 110, the first seal 130, the second seal 150, and the package force applicator 140 described above in connection with FIG. 1. As such, in this example, the first seal 220 defines the first sealed area 135 and the second seal 230 defines the second sealed area 155.

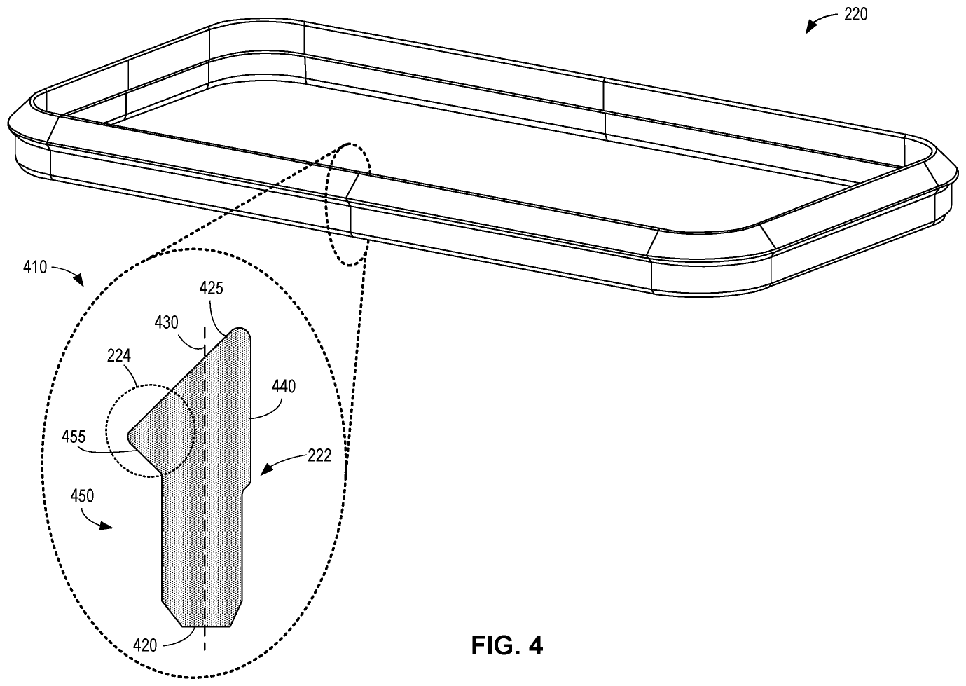

As illustrated in FIG. 2, the example first seal 220 includes a first sidewall 222. The first sidewall 222 of the example first seal 220 abuts against the first die force applicator 210 to allow the first die force applicator 210 to move vertically (e.g., allowing installation of and removing of the first die force applicator 210). A lip portion 224 of the example first seal 220 engages with a first corresponding shape 250 (e.g., complementary shapes) of the first package force applicator 240 to couple with the example package force applicator 240. In some examples, the example package force applicator 240 applies an angled force (e.g., such as a 45 degree force) to the example first seal 220 to force the example first seal 220 in a first (e.g., vertical) direction against the electronic component 160 and in a second (e.g., lateral) direction against the example die force applicator 210. Further detail regarding the example first seal 220 is provided below in connection with FIG. 4.

In some examples, the example second seal 230 has a circular cross-sectional shape and fits within a second corresponding shape 260 (e.g., a groove or recess) of the first package force applicator 240. In other examples, the example second seal 230 may exhibit other shapes such as square, elliptical, triangular, etc. A simplistic shape (e.g., circular, square, etc.) to the example second seal 230 may be desired to reduce design complexities of the first package force applicator 240 and/or the manufacturing/installation of example second seal 230. In some examples, the second example seal assembly 200 includes a first socket 265 (e.g., the first socket 265 is an example implementation of the socket 170 of FIG. 1). In such examples, where the design of the first socket 265 is also simplistic (such as a standard CPU socket on a motherboard where the edges of the first socket 265 are flat/squared), the first package force applicator 240 and the example second seal 230 do not need to conform to or consider any abnormal geometry to apply a force great enough to maintain the electrical connection of the electronic component 160 with the first socket 265. As such, the example second seal 230 may be oriented along a tangential plane with respect to the electronic component 160 (e.g., lying flat on top of the electronic component 160). As disclosed above, the second sealed area 155 is sealed due to the force applied by the first package force applicator 240, and the second sealed area 155 is pressurized by a pressurized gas channel 145 delivering pressurized gas to the second sealed area 155. As shown in FIG. 3, the second seal assembly 200 may include more than one pressurized gas channel 145 for delivering pressurized gas to/from the second sealed area 155. The number of pressurized gas channels 145 may be determined by the area measurement of the second sealed area 155, the type of gas used to pressurize the second sealed area 155, the value of the second pressure desired for the second sealed area 155, etc. In some examples, the pressurized gas may be statically provided (e.g., the pressurized gas is not flowing). In other examples, the pressurized gas is flowing with at least one pressurized gas channel 145 for delivering the pressurized gas to the second sealed area 155 and at least one pressurized gas channel 145 for returning the pressurized gas to a source (e.g., away from the second seal assembly 200).

In the illustrated example of FIG. 2, the electronic component 160 includes an underfill 270 surrounding the die 164. The underfill 270 enables structural coupling of the die 164 and the substrate 162, which decreases shear stress and lowers the applied strain on the solder joints coupling the die 164 and the substrate 162.

In some examples, the example first seal 220 and the electronic component 160 are urged together at a first interface 280. In the examples disclosed herein, the first interface 280 allows the example first seal 220 to be sealingly engaged to the electronic component 160 to define the first sealed area 135. A dotted line is illustrated in FIG. 2 at the first interface 280 to represent the shape of the first seal 220 when uncompressed. As shown, the dotted line overlaps with the electronic component 160 to show an interference fit to achieve the sealing engagement between the example first seal 220 and the electronic component 160.

In the illustrated example of FIG. 2, the second seal assembly 200 includes a gas channel connector 285 for delivering the pressurized gas from the pressurized gas channel 145 to the second sealed area 155. In some examples, where the second seal assembly 200 includes more than one pressurized gas channel 145, each of the pressurized gas channels 145 is connected to its own respective gas channel connector 285 connecting the pressurized gas channel 145 to the second sealed area 155.

In the illustrated example of FIG. 2, the electronic component 160 includes a device stiffener 290 proximate outer edges or a perimeter of the substrate 162. In some examples, the device stiffener 290 allows the example second seal 230 to be urged against a surface other than the substrate 162. In some examples, the device stiffener 290 may be omitted from the electronic component 160 and the example second seal 230 is urged against the substrate 162 directly. Like that of the first interface 280, the example second seal 230 and the electronic component 160 are urged at a second interface 295. In the examples disclosed herein, the second interface 295 allows the example second seal 230 to be sealingly engaged to the electronic component 160 to define the second sealed area 155. A dotted line is illustrated in FIG. 2 at the second interface 295 to represent the shape of the second seal 230 when uncompressed. As shown, the dotted line overlaps with the device stiffener 290 of the electronic component 160 to show an interference fit to achieve the sealing engagement between the example second seal 230 and the device stiffener 290.

In some examples, the second seal assembly 200 includes an ambient area 297 outside of the second sealed area 155. In such an example, the ambient area 297 is subjected to ambient atmosphere conditions and is not modified by the second seal assembly 200. In some examples, a size and shape of the ambient area 297 may be determined by the size and shape of the first socket 265.

FIG. 4 shows the example first seal 220 of the second example seal assembly 200 of FIGS. 2 and 3. A cross-sectional view 410 of the example first seal 220 includes first and second opposing (e.g., lower and upper) surfaces 420 and 425. In this example, the second (e.g., upper) surface 425 is slanted at an angle with respect to a longitudinal axis 430 extending between the first and second surfaces 420 and 425. The second surface 425 is to engage with a surface of the first package force applicator 240 (FIG. 2), and the first surface 420 is to engage with the electronic component 160 (FIG. 2). As shown in the illustrated example, the first seal 220 includes first and second opposing sidewalls 222 and 450. The first sidewall 222 includes the planar first side portion 440 to facilitate vertical movement of the first die force applicator 210 with respect to the top surface of the electronic component 160 (e.g., the die 164).

In some examples, the second sidewall 450 includes a slanted side portion 455 with respect to the planar first side portion 440 of the first sidewall 222 for engaging with a corresponding portion (e.g., the first corresponding shape 250 as described in connection with FIG. 2) of the first package force applicator 240. In some examples, the example first seal 220 includes the lip portion 224 adapted to mate with a mechanical retention portion in the package force applicator 240 (e.g., the first corresponding shape 250) such that the example first seal 220 is retained in place between the first die force applicator 210 and the first package force applicator 240. The lip portion 224 may prevent the example first seal 220 from falling or being pulled out of position once assembled. As illustrated in FIG. 4, the slanted side portion 455 of the second sidewall 450 adjoins the second surface 425 to form the lip portion 224 of the example first seal 220. In some examples, the slanted side portion 455 of the second sidewall 450 adjoins the second surface 425, forming a chamfered corner of the lip portion 224. Thus, the example first seal 220 can self-retain or self-capture while installing the first die force applicator 210 and the first package force applicator 240.

While a specific design for the example first seal 220 is shown and described in FIG. 4, many other seal designs are possible to achieve the advantages of examples disclosed herein. For instance, in some examples, the seal 410 may alternatively be implemented by a generic o-ring and/or any other suitable type of seal (e.g., a rectangular seal, etc.) that is capable of sealingly separating the first sealed area 135 from the second sealed area 155 while allowing the die force applicator 210 and/or the package force applicator 240 to move as discussed herein.

As disclosed above, the first die force applicator 210 and the first package force applicator 240 may apply a force to the electronic component 160 and force the first seal 220 to engage or contact the electronic component 160. In some examples, the force can be applied, externally via air cylinders, to the bottom surface of the first seal 130 (e.g., in contact with the substrate 162) In some examples, the force can be applied to the electronic component 160 which in return applies the necessary load to seal the die force applicator 210 and the package force applicator 240 internally. In other examples, the force may be applied or induced by other mechanisms such as stages, springs, etc.

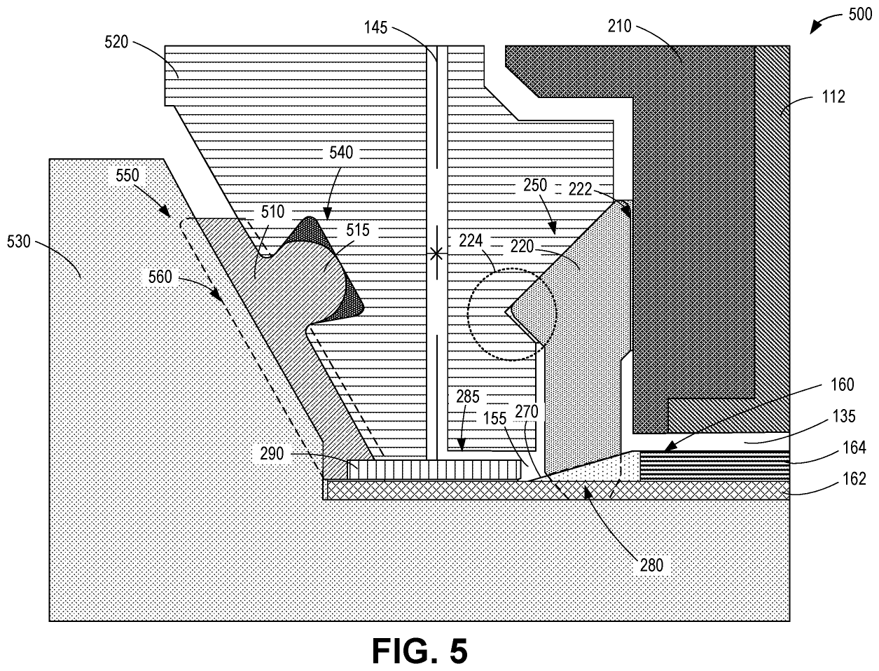

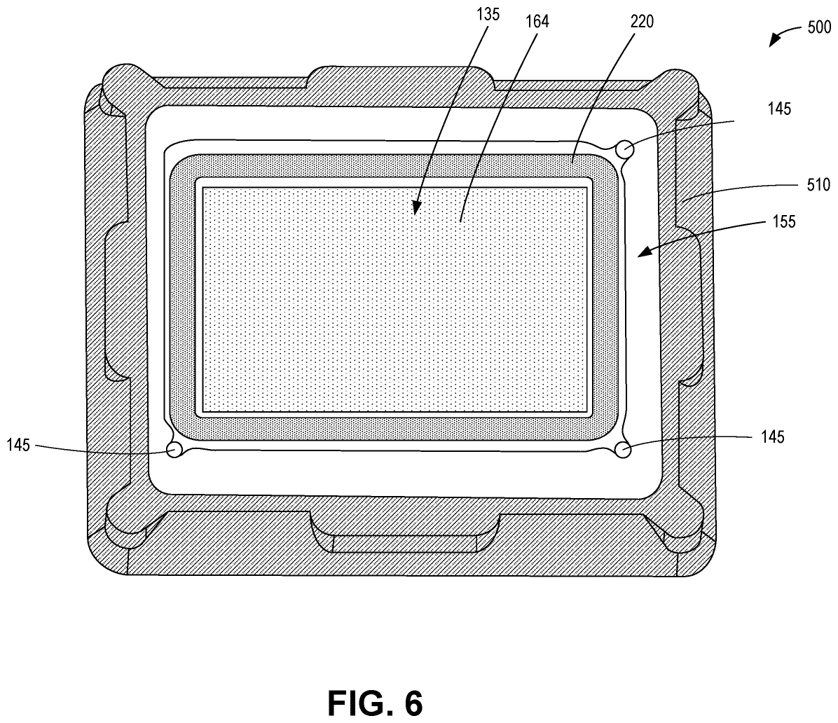

FIG. 5 shows a detailed cross-sectional view of a third seal assembly 500. FIG. 6 is a top view of the third example seal assembly 500. Similar components to those shown and described for the example seal assembly 200 of FIGS. 2-4 use the same reference numbers in FIG. 5-6. Thus, as shown in FIG. 5-6, the third example seal assembly 500 includes the first die force applicator 210, and the example first seal 220. The third example seal assembly 500 further includes an example second seal 510, a second package force applicator 520, and a second socket 530 that are designed differently than corresponding components shown in FIGS. 2 and 3. In the illustrated example of FIG. 6, the die force applicator 210, the second package force applicator 520, and the second socket 530 are omitted to provide a clear view of the spatial relationship of the seals 220, 510. As illustrated in FIG. 5, the example first seal 220 operates in the same way on the third example seal assembly 500 as it does on the second example seal assembly 200 (FIG. 2). Further, the first die force applicator 210, the first seal 220, the second seal 510, and the second package force applicator 520 shown in FIG. 5 are respectively comparable in function, purpose, and operation to the die force applicator 110, the first seal 130, the second seal 150, and the package force applicator 140 described above in connection with FIG. 1. In this example, the socket 530 is shaped in a non-standard manner (e.g., not square, flat, etc.). In some examples, the non-standard shape includes abnormal geometry due to application constraints, performance requirements, etc.

As illustrated in FIG. 5, the second socket 530 and the side of the second package force applicator 520 are shaped to generally conform to one another. In such an example, the example second seal 510 may be shaped (e.g., with one or more protrusions 515) to fit inside, be latched onto, and/or retained by a third corresponding shape 540 (e.g., a groove or recess) on the second package force applicator 520. In some examples, the second socket 530 includes a fourth corresponding shape 550 for allowing the example second seal 510 to be urged against the second socket 530. The fourth corresponding shape 550 of the second socket 530 and the shape of the example second seal 510 are complementary, meaning that the fourth corresponding shape 550 is shaped to specifically support the shape of the example second seal 510. Like that of the first and second example seal assemblies 100, 200, the example second seal 510 of FIG. 5 defines the second sealed area 155 surrounding the example first seal 220, and the example first seal 220 defines the first sealed area 135.

While the examples disclosed above identify the example second seal 510 to include the protrusions 515 that fit inside the third corresponding shape 540, in other examples, the protrusions 515 may be omitted. In such examples, the second seal conforms to the geometry of the second socket 530 and the second package force applicator 520 may not include the third corresponding shape 540. In other examples, the protrusions 515 can have a different shape, size, and/or design relative to what is shown in the illustrated examples. As such, the design of the example second seal 510 can be adjusted/modified to accommodate different applications as necessary.

As disclosed above, the second sealed area 155 is sealed due to the force applied by the second package force applicator 520, and the second sealed area 155 is pressurized by a pressurized gas channel 145 delivering pressurized gas to the second sealed area 155. As shown in FIG. 6, the third seal assembly 500 may include more than one pressurized gas channel 145 for delivering pressurized gas to the second sealed area 155. As disclosed above, the number of pressurized gas channels 145 may be determined by the area measurement of the second sealed area 155, the type of gas used to pressurize the second sealed area 155, the value of the second pressure desired for the second sealed area 155, etc. In some examples, similar to that of the second example seal assembly 200, the pressurized gas may be statically provided (e.g., the pressurized gas is not flowing). In other examples, the pressurized gas is flowing with at least one pressurized gas channel 145 for delivering the pressurized gas to the second sealed area 155 and at least one pressurized gas channel 145 for returning the pressurized gas to a source (e.g., away from the second seal assembly 200).

In the illustrated example of FIG. 5, the electronic component 160 includes the underfill 270 surrounding the die 164 to enable structural coupling of the die 164 and the substrate 162. In this example, the example first seal 220 and the electronic component 160 are urged together at the first interface 280.

As shown in FIG. 5, the third seal assembly 500 includes the gas channel connector 285 for connecting the pressurized gas channel 145 to the second sealed area 155. Similar to that of the second seal assembly 200, where the third seal assembly 500 includes more than one pressurized gas channel 145, each of the pressurized gas channels 145 is connected to its own respective gas channel connector 285.

As shown in FIG. 5, the third seal assembly 500 includes the device stiffener 290. In some examples, the device stiffener 290 allows the example second seal 510 to be urged against a surface other than the substrate 162. The example second seal 510, the second socket 530, and the electronic component 160 are urged at a third interface 560. As such, the example second seal 510 interfaces (e.g., sealingly engages) with the electronic component 160, the third corresponding shape 540 on the second package force applicator 520, and the fourth corresponding shape 550 on the second socket 530. More particularly, in this example, the second seal 510 engages with the electronic component 160 at an outer extremity or perimeter of the substrate 162. A dotted line is illustrated in FIG. 5 at the third interface 560 to represent the shape of the second seal 510 when uncompressed. As shown, the dotted line overlaps with the second socket 530 and the electronic component to show an interference fit to achieve the sealing engagement between the example second seal 510, the second socket 530, and the electronic component 160.

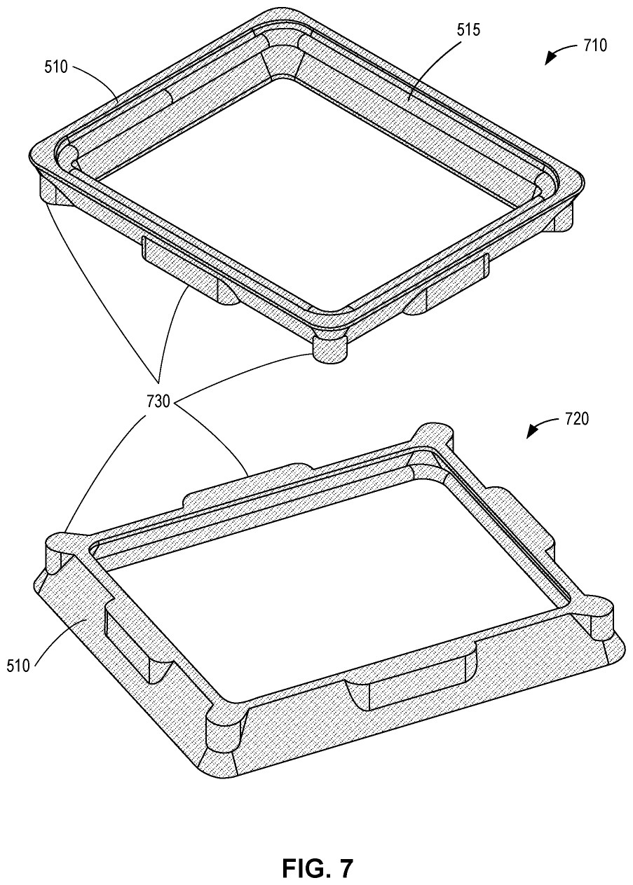

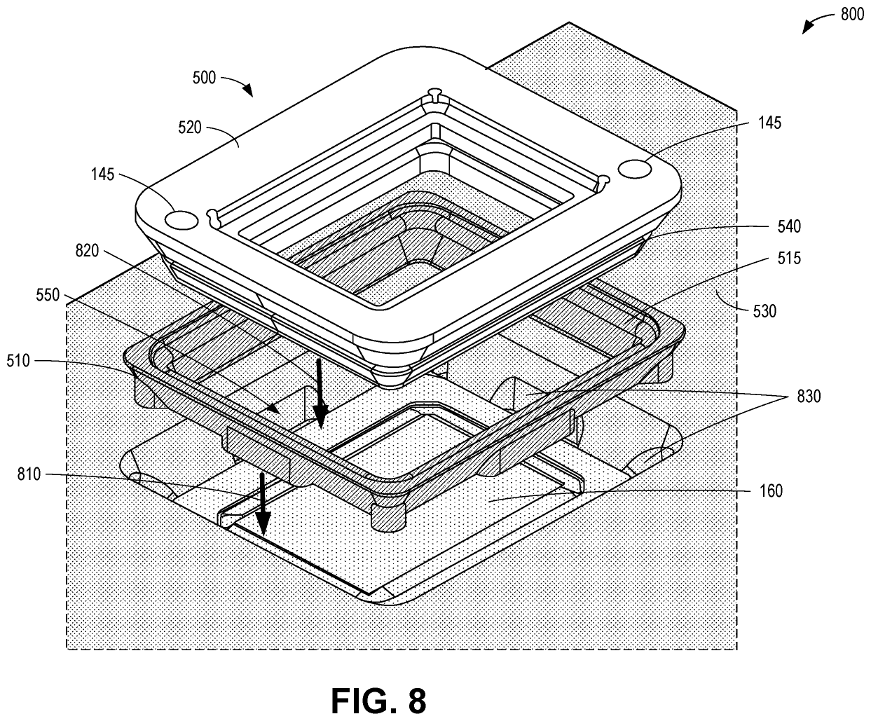

FIG. 7 shows isometric views of the example second seal 510 for the second example seal assembly 500 of FIG. 5. A top view 710 and a bottom view 620 show socket interface protrusions 730 for interfacing with and/or fitting within corresponding recesses 830 (FIG. 8) in the second socket 530. In some examples, the second socket 530 may extend above the plane of the electronic component 160 (e.g., the second socket 530 conforms to the side of the second package force applicator 520 as disclosed in reference to FIG. 5), and the example second seal 510 accommodates the geometry of the second socket 530. In some examples, the example second seal 510 may include more or fewer socket interface protrusions 730 than what is shown in FIG. 7. Further, in some examples, the socket interface protrusions 730 may differ in shape and/or size than what is shown in FIG. 7 for increasing compatibility with the second socket 530 geometry to maintain the sealing force on the example second seal 510. In some examples, the electronic component 160 drives the geometry of the second socket 530 (e.g., the geometry is defined to accommodate the electronic component 160). Such driving factors may include a height of the substrate 162 and/or a height of the die 164, the product in which the electronic component 160 is to operate in, etc.

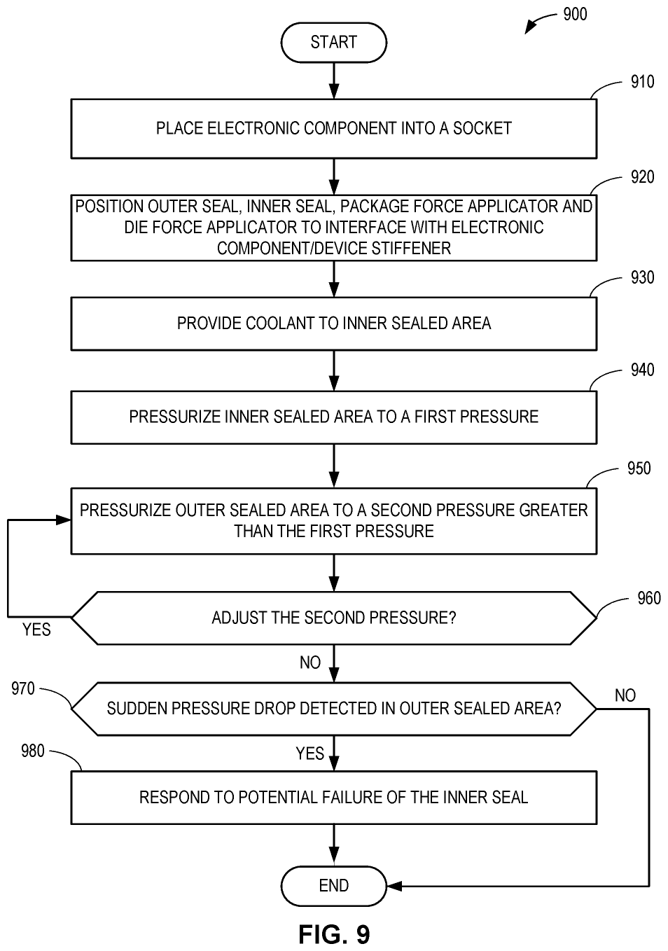

FIG. 8 shows an exploded view 800 of the third example seal assembly 500 of FIGS. 5-7. In FIG. 8, the die force applicator 210 and the first seal 220 are omitted for the sake of clarity and purposes of explanation. In the illustrated example of FIG. 8, the electronic component 160 is installed into the second socket 530. The example second seal 510 is then moved into position to fit into the second socket 530 and surround the electronic component 160 (illustrated by arrow 810). The second package force applicator 520 is then moved into position to latch onto (e.g., by the third corresponding shape 540 mating with the protrusion 515 as shown in FIG. 5) and compress the example second seal 510 (illustrated by arrow 820) to provide the sealing force on the example second seal 510 while an external force (e.g., air cylinders, stages, springs, etc. as disclosed above) is applied to the second package force applicator 520. In some examples, the second seal 510 is latched or coupled onto the second package force applicator 520 before insertion into the socket. Further, in some examples, the first seal 220 is latched or coupled onto the second package force applicator 520 (e.g., via the lip portion 224 of the first seal 220 as shown in FIG. 5). The process for installing the third example seal assembly 500 of FIGS. 5-7 is further described in connection with FIG. 9. Although the process described herein is performed in reference to the third example seal assembly 500, the process may be interchangeably used herein with the first and second seal assemblies 100, 200.

While an example manner of implementing the installation process of FIG. 8 is illustrated in FIG. 9, one or more of the elements and/or processes FIG. 9 may be combined, divided, re-arranged, omitted, eliminated, and/or implemented in any other way. Further, the example installation process of FIG. 8 may include one or more elements and/or processes in addition to, or instead of, those illustrated in FIG. 9, and/or may include more than one of any or all of the illustrated elements and/or processes.

FIG. 9 is a flowchart representative of an example process for implementing the first, second, and/or the third seal assembly 100, 200, 500 of FIGS. 1-8. The example seal assembly implementation process 900 begins at block 910 where the electronic component 160 (e.g., a central processing unit (CPU), an integrated circuit (IC), etc.) is placed into the socket 170, 265, 530. In some examples, the electronic component 160 may include more than one component to install. In other examples, the electronic component 160 includes a single component to install into the socket 170, 265, 530.

An outer seal (e.g., the second seal 150, 230, 510), an inner seal (e.g., the first seal 130, 220), the package force applicator 140, 240, 520, and the die force applicator 110, 210 are then placed/positioned to interface with the electronic component 160. (Block 920). In some examples, the outer seal 150, 230, 510, the inner seal 130, 220, and the package force applicator 140, 240, 520 are assembled together and placed in the seal assembly 100, 200, 500, and then the die force applicator 110, 210 is positioned. In other examples, the inner seal 130, 220 and the die force applicator 110, 210 can be positioned after the outer seal 150, 230, 510 and the package force applicator 140, 240, 520 are positioned. Further, in some examples, the outer seal 150, 230, 510, the inner seal 130, 220, the package force applicator 140, 240, 520 and the die force applicator 110, 210 are all coupled together and positioned simultaneously.

Once the electronic component 160, the outer seal 150, 230, 510, the package force applicator 140, 240, 520, the inner seal 130, 220, and the die force applicator 110, 210 are placed/positioned, coolant can then be provided to the inner sealed area 135. (Block 930).

The inner sealed area 135 is then pressurized to the first pressure. (Block 940). In some examples, the inner sealed area 135 is pressurized as the coolant is being provided to the inner sealed area 135. In some examples, the inner sealed area 135 may be pressurized to the first pressure via the channel 112 in the die force applicator 110, 210. In some examples, the first pressure is a target pressure that may be selected for the particular application the electronic component 160 is to be used in.

The outer sealed area is injected with the pressurized gas to pressurize the outer sealed area 155 to the second pressure. (Block 950). The outer sealed area 155 is pressurized with a pressurized gas to a second pressure that is greater than the first pressure of the inner sealed area 135.

In some examples, the second pressure is then monitored to see if the second pressure should be adjusted. (Block 960). In some examples, the second pressure is modulated (e.g., adjusting the value of the second pressure) based on a monitoring of the first pressure to ensure the second pressure is greater than the first pressure. If the second pressure falls below a threshold (e.g., less than 0.1 atmospheres greater than the first pressure, block 960 returns a result of YES), the example seal assembly implementation process 900 can adjust or re-pressurize the outer sealed area (e.g., return to block 950).

In some examples, the second pressure is monitored for sudden pressure losses/drops and/or flow rate changes to identify potential failures in the inner seal 130, 220. (Block 970). If the second pressure is at an adequate value compared to the first pressure (e.g., block 960 returns a result of NO) and a sudden drop in pressure is detected in the outer sealed area 155 (e.g., block 970 returns a result of YES), then a response to a potential failure in the inner seal 130, 220 is identified. (Block 980). In some examples, the response includes generating an alert, stopping the flow of the cooling fluid 120, etc.

If there is no sudden pressure drop detected in the outer sealed area 155 (e.g., block 970 returns a result of NO) or the response to the sudden pressure drop has been provided, then the example seal assembly implementation process 900 ends.

From the foregoing, it will be appreciated that example systems, methods, apparatus, and articles of manufacture have been disclosed that reduce leakage of a cooling fluid used to cool an electronic component.

Example methods, apparatus, systems, and articles of manufacture to reduce leakage of a cooling fluid used to cool an electronic component are disclosed herein. Further examples and combinations thereof include the following:
Example 1 includes a seal assembly comprising a socket to receive an electronic component, the electronic component including a semiconductor die and a substrate to support the die, a first seal to be forced against the electronic component, the first seal to surround the die, and a second seal to be forced against the electronic component, the second seal to surround the first seal.
Example 2 includes the seal assembly of example 1, wherein the first seal is to be forced toward a surface of the substrate of the electronic component, the die mounted to the surface of the substrate.
Example 3 includes the seal assembly of example 2, wherein the second seal is to be forced into direct contact with at least one of the substrate or a device stiffener disposed on the surface of the substrate.
Example 4 includes the seal assembly of example 1, wherein the second seal has a first shape and the socket has a second shape, the first shape complementary to the second shape, the first shape of the second seal to align with the second shape of the socket.
Example 5 includes the seal assembly of example 1, wherein the first seal defines a first sealed area, the die to be positioned within the first sealed area, the first seal to retain a cooling fluid within the first sealed area.
Example 6 includes the seal assembly of example 5, wherein the second seal defines a second sealed area outside of the first sealed area, the second seal to retain a gas within the second sealed area.
Example 7 includes the seal assembly of example 6, wherein the first sealed area is associated with a first pressure and the second sealed area is associated with a second pressure.
Example 8 includes the seal assembly of example 7, further including a third area outside of the second sealed area that is exposed to an ambient atmosphere.
Example 9 includes the seal assembly of example 1, further including a package force applicator to force the first seal and the second seal against the electronic component.
Example 10 includes the seal assembly of example 9, wherein the package force applicator includes a channel to deliver a pressurized gas to an area between the first seal and the second seal.
Example 11 includes a seal assembly comprising a socket to receive an electronic component, and a first seal to be urged into sealing engagement with the electronic component, the first seal to separate a first sealed area from a second sealed area, the first sealed area to contain a coolant, the coolant to directly contact the electronic component, the first sealed area to be at a first pressure, the second sealed area to be at a second pressure greater than the first pressure.
Example 12 includes the seal assembly of example 11, further including a second seal to be urged toward the electronic component, the second seal to surround the first seal, the second seal to define the second sealed area.
Example 13 includes the seal assembly of example 12, further including a package force applicator positioned between the first seal and the second seal, the first and second seals to be in sealing engagement with the package force applicator.
Example 14 includes the seal assembly of example 13, wherein the package force applicator includes a channel to provide gas between the first and second seals to the second sealed area.
Example 15 includes the seal assembly of example 14, wherein the gas is at least one of air, nitrogen, or helium.
Example 16 includes a method comprising placing an electronic component into a socket, positioning an inner seal to interface with the electronic component, the inner seal to enclose a semiconductor die of the electronic component within an inner sealed area, the inner sealed area to contain cooling fluid to cool the electronic component, positioning an outer seal to interface with the electronic component, the outer seal to enclose the inner seal, an outer sealed area defined between the inner seal and the outer seal, and providing a gas to the outer sealed area.
Example 17 includes the method of example 16, further including positioning a package force applicator, the package force applicator to enable a sealing force to be applied to the inner seal and the outer seal.
Example 18 includes the method of example 17, further including positioning a die force applicator, the die force applicator including a surface defining the inner sealed area.
Example 19 includes the method of example 16, wherein the inner sealed area is at a first pressure and the outer sealed area is at a second pressure, the method further including modulating the second pressure in response to changes in the first pressure.
Example 20 includes the method of example 19, further including detecting a failure of the inner seal by monitoring for changes in the second pressure.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

What is claimed is:

1. A seal assembly comprising:
a socket to receive an electronic component, the electronic component including a semiconductor die and a substrate to support the die;
a first seal to be forced against the electronic component, the first seal to surround the die; and
a second seal to be forced against the electronic component, the second seal to surround the first seal.

2. The seal assembly of claim 1, wherein the first seal is to be forced toward a surface of the substrate of the electronic component, the die mounted to the surface of the substrate.

3. The seal assembly of claim 2, wherein the second seal is to be forced into direct contact with at least one of the substrate or a device stiffener disposed on the surface of the substrate.

4. The seal assembly of claim 1, wherein the second seal has a first shape and the socket has a second shape, the first shape complementary to the second shape, the first shape of the second seal to align with the second shape of the socket.

5. The seal assembly of claim 1, wherein the first seal defines a first sealed area, the die to be positioned within the first sealed area, the first seal to retain a cooling fluid within the first sealed area.

6. The seal assembly of claim 5, wherein the second seal defines a second sealed area outside of the first sealed area, the second seal to retain a gas within the second sealed area.

7. The seal assembly of claim 6, wherein the first sealed area is associated with a first pressure and the second sealed area is associated with a second pressure.

8. The seal assembly of claim 7, further including a third area outside of the second sealed area that is exposed to an ambient atmosphere.

9. The seal assembly of claim 1, further including a package force applicator to force the first seal and the second seal against the electronic component.

10. The seal assembly of claim 9, wherein the package force applicator includes a channel to deliver a pressurized gas to an area between the first seal and the second seal.

11. A seal assembly comprising:
a socket to receive an electronic component; and
a first seal to be urged into sealing engagement with the electronic component, the first seal to separate a first sealed area from a second sealed area, the first sealed area to contain a coolant, the coolant to directly contact the electronic component, the first sealed area to be at a first pressure, the second sealed area to be at a second pressure greater than the first pressure.

12. The seal assembly of claim 11, further including a second seal to be urged toward the electronic component, the second seal to surround the first seal, the second seal to define the second sealed area.

13. The seal assembly of claim 12, further including a package force applicator positioned between the first seal and the second seal, the first and second seals to be in sealing engagement with the package force applicator.

14. The seal assembly of claim 13, wherein the package force applicator includes a channel to provide gas between the first and second seals to the second sealed area.

15. The seal assembly of claim 14, wherein the gas is at least one of air, nitrogen, or helium.

16. A method comprising:
placing an electronic component into a socket;
positioning an inner seal to interface with the electronic component, the inner seal to enclose a semiconductor die of the electronic component within an inner sealed area, the inner sealed area to contain cooling fluid to cool the electronic component;
positioning an outer seal to interface with the electronic component, the outer seal to enclose the inner seal, an outer sealed area defined between the inner seal and the outer seal; and
providing a gas to the outer sealed area.

17. The method of claim 16, further including positioning a package force applicator, the package force applicator to enable a sealing force to be applied to the inner seal and the outer seal.

18. The method of claim 17, further including positioning a die force applicator, the die force applicator including a surface defining the inner sealed area.

19. The method of claim 16, wherein the inner sealed area is at a first pressure and the outer sealed area is at a second pressure, the method further including modulating the second pressure in response to changes in the first pressure.

20. The method of claim 19, further including detecting a failure of the inner seal by monitoring for changes in the second pressure.
